(19) United States
(12) Patent Application Publication
(10) Pub. No.: US 2025/0306076 A1
(43) Pub. Date: Oct. 2, 2025

(54) MEASUREMENT APPARATUS, MEASUREMENT COMPENSATION APPARATUS AND MEASUREMENT METHOD

(71) Applicant: NIPPON TELEGRAPH AND TELEPHONE CORPORATION, Tokyo (JP)

(72) Inventors: Akira KAWAI, Musashino-shi (JP); Shimpei SHIMIZU, Musashino-shi (JP); Takayuki KOBAYASHI, Musashino-shi (JP); Yutaka MIYAMOTO, Musashino-shi (JP)

(73) Assignee: NIPPON TELEGRAPH AND TELEPHONE CORPORATION, Tokyo (JP)

(21) Appl. No.: 18/860,402

(22) PCT Filed: May 9, 2022
(86) PCT No.: PCT/JP2022/019661

§ 371 Date: Oct. 25, 2024

(51) Int. Cl. G01R 29/08; G01M 11/00

(52) U.S. Cl. CPC G01R 29/0885; G01M 11/331

(57) ABSTRACT

There is provided a measurement apparatus including: an interference waveform generating unit that generates an interference waveform signal corresponding to interference light of first light with second light received by an imaging surface; a distribution measurement unit that measures a first optical electric-field distribution of an intensity and a phase of the first light at the imaging surface, based on the interference waveform signal; a distribution simulation unit that simulates second optical electric-field distributions of the intensity and the phase of the first light at a plurality of planes having different distances from the imaging surface in a direction opposite to a propagation direction of the first light propagated from an end surface of an optical waveguide, based on the measured first optical electric-field distribution; a selection unit that selects, from the plurality of planes, a plane at which an area of a region of the simulated second optical electric-field distributions is minimized; and an output unit that outputs information of the simulated second optical electric-field distributions at the selected plane to a predetermined device.

### TECHNICAL FIELD

The present invention relates to a measurement apparatus, a measurement compensation apparatus and a measurement method.

### BACKGROUND ART

An optical transmission system using an optical fiber as an optical waveguide is widely used as a system that realizes a fixed line having a large transmission capacity due to the wideband property and low loss property of the optical fiber. In order to further increase the transmission capacity, space division multiplexing (SDM) has been studied. In space division multiplexing in an optical transmission system, instead of one single mode fiber (SMF), a plurality of single mode fibers (parallel single mode fibers), a multicore fiber (MCF), a coupled-core multicore fiber (CC-MCF), a multimode fiber (MMF), or a multicore multimode fiber (MCMMF) may be used as an optical waveguide.

A plurality of spatial degrees of freedom of these optical waveguides are utilized as independent channels. This makes it possible to increase the transmission capacity per fiber. The multimode fiber and the multimode multicore fiber (hereinafter, referred to as a “multimode fiber or the like”) can increase the number of modes per unit cross-sectional area of an optical waveguide as compared with a plurality of single mode fibers and multicore fibers. Therefore, a multimode fiber or the like is expected to be used in a spatial multiplexing method with high spatial utilization efficiency (see Non Patent Document 1).

An optical fiber having appropriate performance and a device having a performance corresponding to the input and output of a multimode core need to be provided to construct an optical transmission system using a multimode fiber or the like. Here, in order to appropriately evaluate the performance of the multimode fiber or the like, it is necessary to measure an optical electric-field distribution of the intensity and the phase of the optical signal at an end surface of the multimode fiber or the like. In addition, in order to appropriately design the device, it is necessary to measure the optical electric-field distribution of the intensity and the phase of the optical signal at the end surface of an optical waveguide of the device.

One reason why information (profile) of the optical electric-field distribution is necessary is that the information of the optical electric-field distribution is necessary for evaluating an amount of nonlinear noise generated in an optical waveguide due to a nonlinear optical effect in an optical fiber. Since the nonlinear effect in the optical fiber increases according to optical power, the nonlinear effect becomes an ultimate limiting factor of the transmission capacity. Therefore, the information of the optical electric-field distribution is important from the viewpoint of evaluating performance of a transmission system.

In order to evaluate the nonlinear effect in a multimode fiber or the like, it is necessary to know an area of a region of the optical electric-field distribution at the end surface of the optical waveguide for each mode of the optical signal. The optical electric-field distribution includes information on the intensity and the phase of the optical signal propagated from the end surface of the optical waveguide. In order to calculate the area of the region of the optical electric-field distribution, it is necessary to measure the optical electric-field distribution at the end surface of the optical waveguide (see Non Patent Document 2).

In addition, a reason why the information on the optical electric-field distribution at the end surface of the optical fiber and the end surface of the optical waveguide of the device is necessary for the design of the device is that the information on the optical electric-field distribution is necessary for design of an input/output unit having a lower coupling loss. In the input/output unit that couples optical signals by bringing the optical fiber into contact with the device, the coupling efficiency between the optical waveguide in the device and the optical fiber is determined according to the overlap between a region of the optical electric-field distribution at the end surface of the optical waveguide of the device and a region of the optical electric-field distribution at the end surface of the optical fiber.

Therefore, for the purpose of optimizing the coupling efficiency between the optical waveguide in the device and the optical fiber, both the information of the optical electric-field distribution at the end surface of the optical waveguide of the device and the optical electric-field distribution at the end surface of the optical fiber are measured in advance, and the optical waveguide is designed such that both items of the measured information of the optical electric-field distributions match each other as much as possible.

Digital holography may be used to measure the optical electric-field distribution of the intensity and the phase at the end surface of the optical waveguide (see Non Patent Document 3). In a digital holographic optical system, object light is propagated from an end surface of an optical waveguide, and an imaging surface (image sensor) receives interference light of the object light with reference light (plane wave). By analyzing an interference waveform signal corresponding to the received interference light through digital signal processing, the optical electric-field distribution of the intensity and the phase at the end surface of the optical waveguide is measured.

However, in a case where a distance between components of the optical system is not accurately controlled, the measurement accuracy of the optical electric-field distribution at the end surface cannot be improved by an existing method. For example, in a digital holographic optical system, it is necessary to accurately control a distance between an end surface of an optical waveguide and an imaging optical system, a distance between lenses in the imaging optical system, and a distance between the imaging optical system and an imaging surface. In a case where a distance between the components of the optical system is different from the ideal distance, an image of the measured optical electric-field distribution is an image in which a region of the optical electric-field distribution at the end surface of the optical waveguide is defocused. Therefore, the measurement accuracy of the optical electric-field distribution at the end surface of the optical waveguide cannot be improved. In view of such a problem, defocus compensation may be performed on an image so that the clarity (contour sparsity) of an image of an optical electric-field distribution is maximized by a method similar to that of a case where defocus compensation is performed so that the clarity of an image of a biological microscope is maximized (see Non Patent Document 4).

### CITATION LIST

### Non Patent Documents

Non Patent Document 1: Mizuno, Takayuki, et al. “Dense space-division multiplexed transmission systems using multi-core and multi-mode fiber.” Journal of lightwave technology 34.2 (2016): pp. 582-592.

Non Patent Document 2: Rademacher, Georg, and Klaus Petermann. “Nonlinear Gaussian noise model for multimode fibers with space-division multiplexing.” Journal of Lightwave Technology 34.9 (2016): pp. 2280-2287.

Non Patent Document 3: Shimizu, Shimpei, et al. “Volume holographic spatial mode demultiplexer with a dual-wavelength method.” Applied optics 57.2 (2018): pp. 146-153.

Non Patent Document 4: Zhang, Yibo, et al. “Edge sparsity criterion for robust holographic autofocusing.” Optics letters 42.19 (2017): pp. 3824-3827.

### SUMMARY OF INVENTION

### Technical Problem

However, an image of an optical electric-field distribution of multimode light at an end surface of an optical waveguide has an unclear edge for both a real part and a virtual part, for example, like an edge of an image of an optical electric-field distribution of an LP 11 mode. Therefore, it is difficult to clarify the edge of the image of the optical electric-field distribution (compensate for defocus) by a method similar to correction for an image of the biological microscope or a natural image.

As described above, in a case where the distance between the components of the optical system is not accurately controlled, a problem arises in that measurement accuracy of the optical electric-field distribution at the end surface of the optical waveguide cannot be improved.

In view of the above circumstances, objects of the present invention are to provide a measurement apparatus, a measurement compensation device, and a measurement method capable of improving measurement accuracy of an optical electric-field distribution at an end surface of an optical waveguide even in a case where a distance between components of an optical system is not accurately controlled.

### Solution to Problem

According to one aspect of the present invention, there is provided a measurement apparatus including: an interference waveform generating unit that generates an interference waveform signal corresponding to interference light of first light with second light received by an imaging surface; a distribution measurement unit that measures a first optical electric-field distribution of an intensity and a phase of the first light at the imaging surface, based on the interference waveform signal; a distribution simulation unit that simulates second optical electric-field distributions of the intensity and the phase of the first light at a plurality of planes having different distances from the imaging surface in a direction opposite to a propagation direction of the first light propagated from an end surface of an optical waveguide, based on the measured first optical electric-field distribution; a selection unit that selects, from the plurality of planes, a plane at which an area of a region of the simulated second optical electric-field distributions is minimized; and an output unit that outputs information of the simulated second optical electric-field distributions at the selected plane to a predetermined device.

According to another aspect of the present invention, there is provided a measurement compensation device including: a distribution measurement unit that measures a first optical electric-field distribution of an intensity and a phase of first light at an imaging surface, based on an interference waveform signal corresponding to interference light of the first light and second light received at the imaging surface; a distribution simulation unit that simulates second optical electric-field distributions of the intensity and the phase of the first light at a plurality of planes having different distances from the imaging surface in a direction opposite to a propagation direction of the first light propagated from an end surface of an optical waveguide, based on the measured first optical electric-field distribution; a selection unit that selects, from the plurality of planes, a plane at which an area of a region of the simulated second optical electric-field distributions is minimized; and an output unit that outputs information of the simulated second optical electric-field distributions at the selected plane to a predetermined device.

According to still another aspect of the present invention, there is provided a measurement method performed by a measurement apparatus, the method including: a step of generating an interference waveform signal corresponding to interference light of first light with second light received by an imaging surface; a step of measuring a first optical electric-field distribution of an intensity and a phase of the first light at the imaging surface, based on the interference waveform signal; a step of simulating second optical electric-field distributions of the intensity and the phase of the first light at a plurality of planes having different distances from the imaging surface in a direction opposite to a propagation direction of the first light propagated from an end surface of an optical waveguide, based on the measured first optical electric-field distribution; a step of selecting, from the plurality of planes, a plane at which an area of a region of the simulated second optical electric-field distributions is minimized; and a step of outputting information of the simulated second optical electric-field distributions at the selected plane to a predetermined device.

### Advantageous Effects of Invention

As described above, even in a case where a distance between components of an optical system is not accurately controlled, measurement accuracy of an optical electric-field distribution at an end surface of an optical waveguide can be improved.

### BRIEF DESCRIPTION OF DRAWINGS

FIG. 1 is a diagram illustrating a configuration example of a measurement apparatus according to a first embodiment.

FIG. 2 is a diagram illustrating an example of an optical electric-field distribution of an intensity and a phase of object light in the first embodiment.

FIG. 3 is a flowchart illustrating an operation example of a measurement compensation device according to the first embodiment.

FIG. 4 is a diagram illustrating a configuration example of a measurement apparatus according to a second embodiment.

FIG. 5 is a diagram illustrating a hardware configuration example of the measurement apparatus in each embodiment.

### DESCRIPTION OF EMBODIMENTS

Embodiments of the present invention are described below in detail, with reference to the drawings.

### First Embodiment

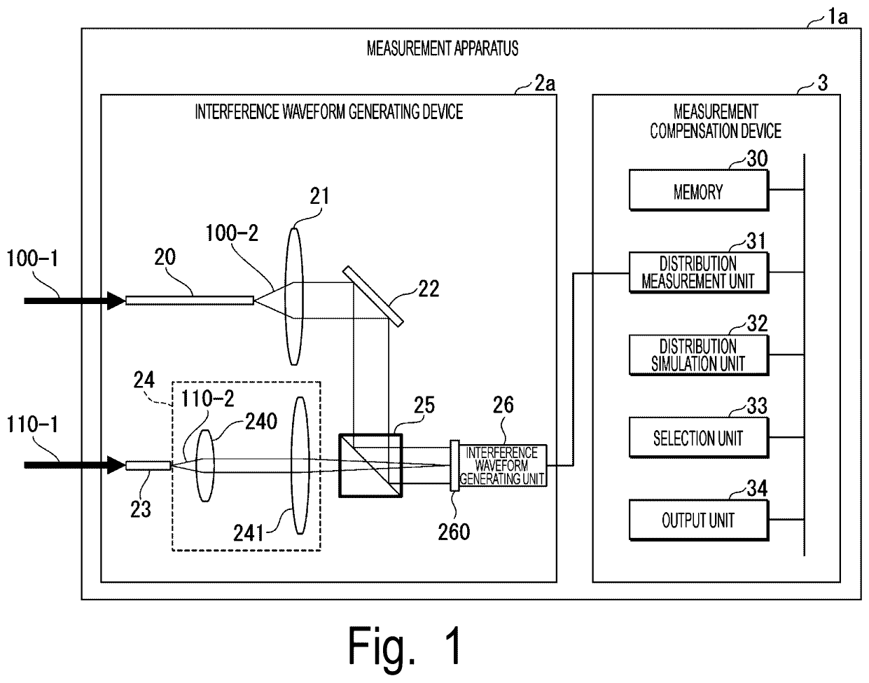

FIG. 1 is a diagram illustrating a configuration example of a measurement apparatus 1a according to an embodiment. The measurement apparatus 1a is an apparatus that measures an optical electric-field distribution at an end surface of an optical waveguide. The measurement apparatus 1a includes an interference waveform generating device 2a and a measurement compensation device 3.

First, the interference waveform generating device 2a will be described.

The interference waveform generating device 2a is a device that generates a signal (interference waveform signal) corresponding to interference light. The interference waveform generating device 2a includes, for example, an off-axis type or in-line type digital holographic optical system. In FIG. 1, the interference waveform generating device 2a includes an optical waveguide 20, a collimator lens 21, a mirror 22, an optical waveguide 23, an imaging optical system 24, a beam splitter 25, and an interference waveform generating unit 26 as components in the off-axis digital holographic optical system.

The imaging optical system 24 includes a lens 240 and a lens 241 as a pair of lenses. The imaging optical system 24 may include a plurality of lenses in which aberrations and magnifications are considered instead of including the pair of lenses. The interference waveform generating unit 26 includes an imaging surface 260 (image sensor).

The optical waveguide 20 is, for example, an optical fiber such as a single mode fiber. The optical waveguide 20 may contain a material such as silicon or indium phosphide. Reference light 100-1 is input to the optical waveguide 20. The optical waveguide 20 transmits the reference light 100-1. The optical waveguide 20 outputs reference light 100-2 to the collimator lens 21.

The collimator lens 21 outputs the reference light 100-2 (a plane wave having a predetermined inclination) to the mirror 22. The mirror 22 reflects the reference light 100-2 to the beam splitter 25. Note that the reference light 100-2 propagated from the end surface of the optical waveguide 20 (single mode fiber) may be used as an approximate plane wave without using the collimator lens 21. In addition, the reference light 100-2 propagated from a pinhole may be used as the approximate plane wave without using the optical waveguide 20.

The optical waveguide 23 is, for example, a multimode fiber or the like (spatial multiplexing fiber or the like). The optical waveguide 23 may contain a material such as silicon or indium phosphide. Object light 110-1 is input to the optical waveguide 23. The optical waveguide 23 transmits the object light 110-1. The optical waveguide 23 outputs object light 110-2 to the imaging optical system 24.

The object light 110-2 is input to the imaging optical system 24 from the optical waveguide 23. The imaging optical system 24 forms an image of an optical electric-field distribution of the object light 110-2 on the imaging surface 260 (focal plane) using the lens 240 and the lens 241.

The object light 110-2 output from the imaging optical system 24 penetrates the beam splitter 25. The reference light 100-2 reflected by the mirror 22 is input to the beam splitter 25. The beam splitter 25 reflects the reference light 100-2 to the imaging surface 260.

The interference waveform generating unit 26 is, for example, a near-infrared camera. The object light 110-2 is input from the beam splitter 25 to the imaging surface 260. The reference light 100-2 is input from the beam splitter 25 to the imaging surface 260. Consequently, the imaging surface 260 receives interference light of the object light 110-2 with the reference light 100-2. The imaging surface 260 images the interference light of the object light 110-2 with the reference light 100-2. The interference waveform generating unit 26 generates an interference waveform signal according to the interference light received by the imaging surface 260. The interference waveform generating unit 26 outputs the interference waveform signal to the measurement compensation device 3.

Next, the measurement compensation device 3 will be described.

The measurement compensation device 3 is a device that measures an optical electric-field distribution. Here, the measurement compensation device 3 compensates for a measurement result. The object light 110-2 propagated from the end surface of the optical waveguide 23 spatially spreads in a propagation direction and a vertical direction. The measurement compensation device 3 uses that above-described point to compensate for information (measurement result) of the defocused optical electric-field distribution at the imaging surface 260 by digital signal processing. In this digital signal processing, advance information such as a deviation from a focal distance and a defocus distance of the optical system is unnecessary.

The measurement compensation device 3 includes a memory 30, a distribution measurement unit 31, a distribution simulation unit 32, a selection unit 33, and an output unit 34. The memory 30 stores the interference waveform signal output from the interference waveform generating unit 26. The memory 30 may store a computer program in advance.

The distribution measurement unit 31 (complex distribution demodulation unit) acquires the interference waveform signal corresponding to the interference light from the memory 30 or the interference waveform generating unit 26. The distribution measurement unit 31 performs two-dimensional Fourier transform on the acquired interference waveform signal. The distribution measurement unit 31 performs low-pass filter processing on a result of the two-dimensional Fourier transform. For example, the distribution measurement unit 31 extracts an appropriate band as a spatial frequency of the object light 110-2 from the result of the two-dimensional Fourier transform.

The distribution measurement unit 31 performs a frequency shift on a band extracted by the low-pass filter processing to the vicinity of the frequency “0”. The distribution measurement unit 31 performs two-dimensional inverse Fourier transform (demodulation) on the result of the two-dimensional Fourier transform of the band subjected to the frequency shift to the vicinity of the frequency “0”. Consequently, information of the optical electric-field distribution (complex distribution) at the imaging surface 260 is derived.

The distribution simulation unit 32 virtually changes a propagation distance of the object light 110 in a digital region by calculation on the basis of the information of the optical electric-field distribution at the imaging surface 260. That is, the distribution simulation unit 32 simulates the optical electric-field distribution on individual virtual planes for individual planes virtually defined at a plurality of positions in the propagation direction of the object light 110.

The distribution simulation unit 32 simulates the optical electric-field distribution at each virtual plane by using, for example, an angular spectrum method (Reference 1: Matsushima, Kyoji, and Tomoyoshi Shimobaba. “Band-limited angular spectrum method for numerical simulation of free-space propagation in far and near fields.” Optics express 17.22 (2009): pp. 19662-19673). Consequently, information of the optical electric-field distribution (complex distribution) at each virtual plane is derived.

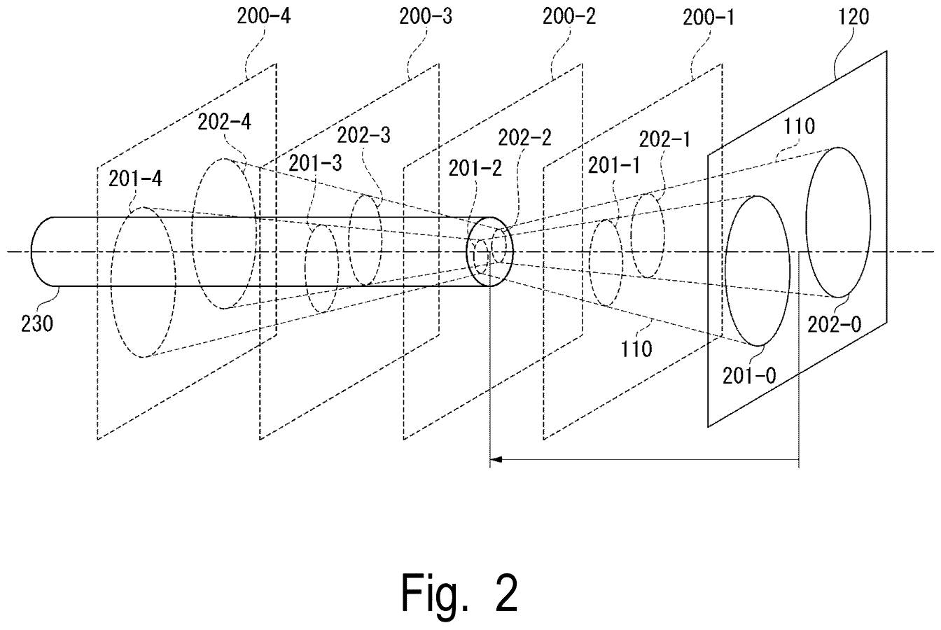

FIG. 2 is a diagram illustrating an example of an optical electric-field distribution of an intensity and a phase of the object light 110-2 in the first embodiment. A core 230 is a core of the optical waveguide 23. A plane 120 is a focal plane of the lens 241. Individual planes 200 are individual planes (individual planes of a digital region) virtually defined at the plurality of positions in the propagation direction from the optical waveguide 23 toward the imaging surface 260.

In FIG. 2, the information (profile) of the defocused optical electric-field distribution obtained as the interference waveform signal is information of an optical electric-field distribution of a region 201-0 and a region 202-0 at the plane 120 (imaging surface 260) away from the end surface of the optical waveguide 23.

The distribution simulation unit 32 simulates propagation of the object light 110 in the real space, in a digital region through the digital signal processing. The distribution simulation unit 32 derives a region 201 and a region 202 of an optical electric-field distribution at each plane 200 by propagating the object light 110 in a forward direction or a reverse direction of the propagation direction in the digital region.

For example, the distribution simulation unit 32 virtually moves the region 201-0 and the region 202-0 of the measured optical electric-field distribution through the digital signal processing in a direction opposite to the propagation direction of the object light 110, by a distance corresponding to a focal distance and a defocus distance of the imaging optical system 24. Here, if an appropriate distance (accurate propagation distance) is determined as a movement distance of the region 201-0 and the region 202-0, the measurement compensation device 3 can compensate for defocus of an image of an optical electric-field distribution by propagating the object light 110 in the digital region.

The object light 110 propagated from the end surface of the core 230 spatially spreads in the propagation direction and the vertical direction. In other words, the areas of a region 201-2 and a region 202-2 of the optical electric-field distribution at a plane 200-2 (the end surface of the core 230) are the smallest of the areas of the regions 201 and 202 of the optical electric-field distribution at the planes 200. Hence, an appropriate distance (accurate propagation distance) as the movement distance of the region 201-0 and the region 202-0 is a propagation distance between the plane 200-2 and the plane 120.

For example, the distribution simulation unit 32 uses regions of a two-dimensional distribution such as a Gaussian distribution, as a parameter, and quantifies a beam diameter of the object light 110 by fitting the regions of the two-dimensional distribution to the region 201 and the region 202 of the measured optical electric-field distribution of the object light 110, respectively.

For example, the distribution simulation unit 32 may derive a variance in the measurement values of the intensity and the phase in the region of the optical electric-field distribution of the object light 110 along two-dimensional axes representing the plane 120. The distribution simulation unit 32 may quantify the beam diameter of the object light 110, based on the derived variance in the measurement values.

The selection unit 33 compares the areas of the region 201 and the region 202 of the simulated optical electric-field distribution for the plurality of planes 200. The selection unit 33, from the plurality of planes 200, selects a plane 200 at which the areas of the region 201 and the region 202 of the optical electric-field distribution is minimized. In FIG. 2, the selection unit 33 selects the plane 200-2. The position of the plane 200-2 coincides with the position of the end surface of the optical waveguide 23 (core 230). The information of the optical electric-field distribution in the region 201-2 and the region 202-2 is information of an accurate optical electric-field distribution at the end surface of the core 230. As described above, the selection unit 33 detects the region 201-2 and the region 202-2 of the accurate optical electric-field distribution at the end surface of the core 230.

The output unit 34 outputs information of the optical electric-field distribution of the region 201-2 and the region 202-2 at the selected plane 200-2 to a predetermined device (not illustrated). The output unit 34 outputs information indicating a distance (propagation distance) from the selected plane 200-2 to the plane 120 (focal plane) to a predetermined device (not illustrated). Consequently, similarly to the current correction, it is possible to perform defocus correction on the basis of the information indicating the propagation distance in the next and subsequent corrections. In addition, since it is not necessary to simulate the optical electric-field distribution for a plurality of positions, the amount of calculation can be reduced.

Next, an operation example of the measurement apparatus 1a (measurement compensation device 3) will be described.

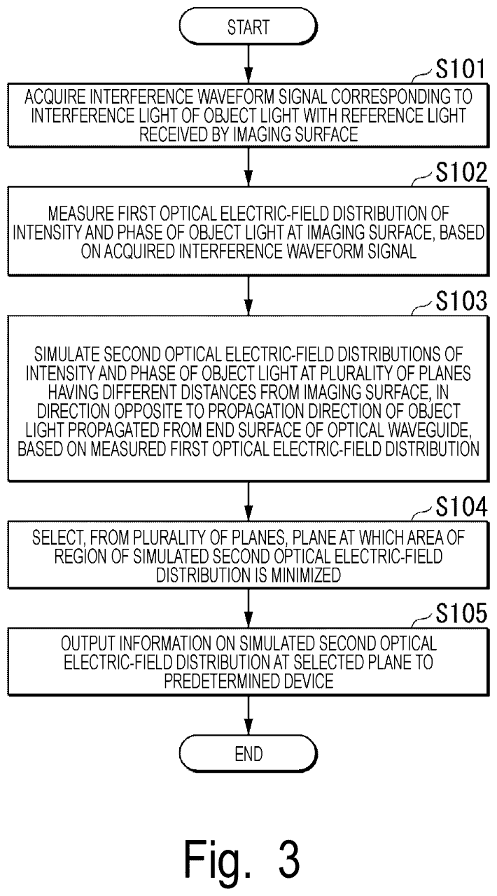

FIG. 3 is a flowchart illustrating an operation example of the measurement compensation device 3 according to the first embodiment. The distribution measurement unit 31 acquires the interference waveform signal corresponding to the interference light of the object light 110 with the reference light 100 received by the imaging surface 260 from the interference waveform generating unit 26 or the memory 30 (step S101).

Based on the acquired interference waveform signal, the distribution measurement unit 31 measures a first optical electric-field distribution of the intensity and the phase of the object light 110 at the imaging surface 260 (step S102). Second optical electric-field distributions of the intensity and the phase of the object light 110 at the plurality of planes 200 having different distances from the imaging surface 260 is simulated in a direction opposite to the propagation direction of the object light 110 propagated from the end surface of the optical waveguide 23, based on the first optical electric-field distribution measured at the imaging surface 260 (step S103).

The selection unit 33 selects, from the plurality of planes 200, a plane 200 at which the area of the region 201 of the simulated second optical electric-field distributions is minimized. The selection unit 33 may select, from the plurality of planes 200, a plane 200 at which the area of the region 202 of the simulated second optical electric-field distributions is minimized (step S104).

The output unit 34 outputs information of the simulated second optical electric-field distributions at the selected plane 200 to a predetermined device (not illustrated) or the memory 30. The output unit 34 may output information on the distance from the selected plane 200 to the plane 120 (focal plane) (propagation distance from the selected plane 200 to the imaging surface 260) to a predetermined device (not illustrated) or the memory 30 (step S105).

As described above, the interference waveform generating unit 26 generates the interference waveform signal according to the interference light of the object light 110 (first light) with the reference light 100 (second light) received by the imaging surface 260. Based on the interference waveform signal, the distribution measurement unit 31 measures the first optical electric-field distribution of the intensity and the phase of the object light 110 at the imaging surface 260. The distribution simulation unit 32 simulates the second optical electric-field distributions of the intensity and the phase of the object light 110 at the plurality of planes 200 having different distances from the imaging surface 260 in the direction opposite to the propagation direction of the object light 110 propagated from the end surface of the optical waveguide 23, based on the measured first optical electric-field distribution. The selection unit 33 selects, from the plurality of planes 200, a plane 200 at which the areas of the region 201 and the region 202 of the simulated second optical electric-field distributions is minimized. The output unit 34 outputs information of the simulated second optical electric-field distributions at the selected plane 200 to a predetermined device (not illustrated).

Consequently, even in a case where a distance between components (arrangement of the components) of the optical system is not accurately controlled, measurement accuracy of the optical electric-field distribution at the end surface of the optical waveguide can be improved. For example, even in a case where the defocus distance or the like of the lens is unknown, it is possible to improve the measurement accuracy of the optical electric-field distribution at the end surface of the optical waveguide. For example, even in a case where an index such as clarity (contour sparsity) of an image is unknown, it is possible to improve the measurement accuracy of the optical electric-field distribution at the end surface of the optical waveguide.

### Second Embodiment

The second embodiment differs from the first embodiment in that the interference waveform generating device does not include the imaging optical system (lens). In the second embodiment, the differences from the first embodiment will be mainly described.

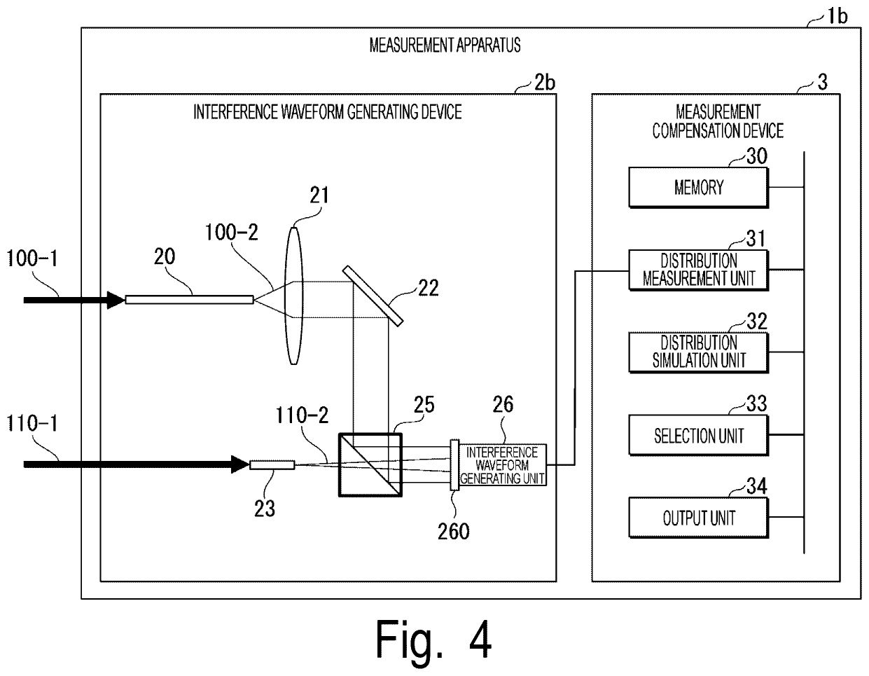

FIG. 4 is a diagram illustrating a configuration example of a measurement apparatus 1b according to the second embodiment. The measurement apparatus 1b is an apparatus that measures an optical electric-field distribution at an end surface of an optical waveguide. The measurement apparatus 1b includes an interference waveform generating device 2b and a measurement compensation device 3.

The interference waveform generating device 2b is a device that generates an interference waveform. The interference waveform generating device 2b includes, for example, an off-axis type or in-line type digital holographic optical system. In FIG. 4, the interference waveform generating device 2b includes an optical waveguide 20, a collimator lens 21, a mirror 22, an optical waveguide 23, a beam splitter 25, and an interference waveform generating unit 26 as components in the off-axis digital holographic optical system.

Object light 110-1 is input to the optical waveguide 23. The optical waveguide 23 transmits the object light 110-1. The optical waveguide 23 outputs the object light 110-2 to the beam splitter 25.

In the second embodiment, since the interference waveform generating device 2b does not include the imaging optical system (lens), the object light 110 is not imaged at the imaging surface 260 by the imaging optical system. The object light 110 propagated from the optical waveguide 23 is received by the imaging surface 260 (image sensor) via the beam splitter 25. The position of the plane 120 and the position of the imaging surface 260 are the same. Here, a propagation distance from the plane 200-2 to the plane 120 in FIG. 2 is equal to a distance from the plane 200-2 to the imaging surface 260.

The object light 110-2 output from the optical waveguide 23 penetrates the beam splitter 25. The reference light 100-2 reflected by the mirror 22 is input to the beam splitter 25. The beam splitter 25 reflects the reference light 100-2 to the imaging surface 260.

The interference waveform generating unit 26 generates an interference waveform signal according to the interference light received by the imaging surface 260. The interference waveform generating unit 26 outputs the interference waveform signal to the measurement compensation device 3. The distribution measurement unit 31 acquires the interference waveform signal from the interference waveform generating unit 26 or the memory 30.

As described above, the imaging surface 260 receives the object light 110-2 propagated from the end surface of the optical waveguide 23 without passing through the imaging optical system 24 (the lens 240 and the lens 241). That is, the imaging surface 260 receives the object light 110-2 propagated from the end surface of the optical waveguide 23 via a lensless optical system.

Consequently, even in a case where a distance between components of an optical system is not accurately controlled, the measurement accuracy of the optical electric-field distribution at the end surface of an optical waveguide can be improved. In a lensless holography measurement system, since it is possible to simulate the spatial propagation of the object light, there is no need to provide a lens for forming an image of the object light at the end surface. Therefore, it is possible to reduce the size, increase the band independent of the lens, and eliminate aberration of the measurement apparatus.

### MODIFICATION EXAMPLES

Instead of measuring the optical electric-field distribution by the measurement apparatus using digital holography, the measurement apparatus may measure the optical electric-field distribution by using a Shack-Hartmann wave-front sensor. In addition, the measurement apparatus may measure the optical electric-field distribution by using a predetermined optimization algorithm. The predetermined optimization algorithm is, for example, the iterative Fourier transform method. The iterative Fourier transform method is, for example, the Gerchberg-Saxton algorithm.

### Hardware Configuration Example

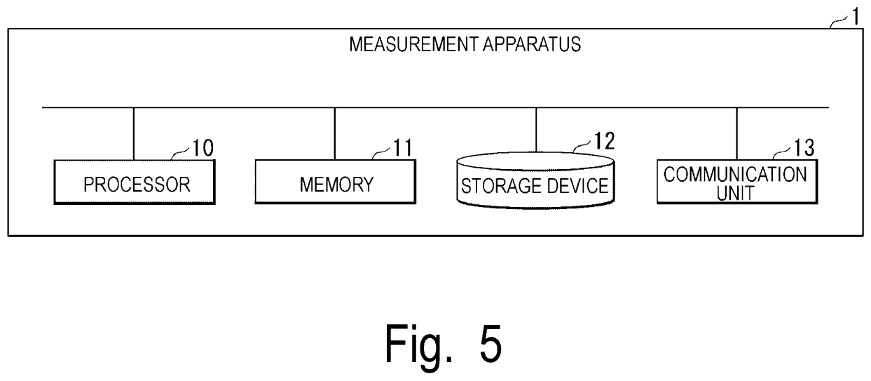

FIG. 5 is a diagram illustrating a hardware configuration example of the measurement apparatus 1 (measurement system) in each embodiment. The measurement apparatus 1 corresponds to a part or the whole of the measurement apparatus 1a and the measurement apparatus 1b.

The measurement apparatus 1 is realized as software by a processor 10 such as a central processing unit (CPU) executing a program stored in a storage device 12 including a nonvolatile recording medium (non-transitory recording medium) and a memory 11. The program may be recorded in a computer-readable non-transitory recording medium. The computer-readable non-transitory recording medium is, for example, a portable medium such as a flexible disk, a magneto-optical disk, a read only memory (ROM), or a compact disc read only memory (CD-ROM), or a non-transitory recording medium such as a storage device such as a hard disk built in a computer system. A communication unit 13 performs a predetermined communication process.

Some or all of the functional units of the measurement apparatus 1 may be realized by using hardware including an electronic circuit (electronic circuit or circuitry) in which, for example, a large scale integrated circuit (LSI), an application specific integrated circuit (ASIC), a programmable logic device (PLD), a field programmable gate array (FPGA), or the like is used.

Although the embodiments of this invention have been described in detail with reference to the drawings, specific configurations are not limited to this embodiment and include design and the like within the scope without departing from the concept of this invention.

### INDUSTRIAL APPLICABILITY

The present invention is applicable to an apparatus (light measurement apparatus) that measures an optical electric-field distribution.

### REFERENCE SIGNS LIST

1, 1a, 1b Measurement apparatus
2a, 2b Interference waveform generating device
3 Measurement compensation device
20 Optical waveguide
21 Collimator lens
22 Mirror
23 Optical waveguide
24 Imaging optical system
25 Beam splitter
26 Interference waveform generating unit
30 Memory
31 Distribution measurement unit
32 Distribution simulation unit
33 Selection unit
34 Output unit
100 Reference light
110 Object light
120 Plane
200 Plane
201 Region
202 Region
230 Core
240 Lens
241 Lens
260 Imaging surface

1. A measurement apparatus comprising:
an interference waveform generator that generates an interference waveform signal corresponding to interference light of first light with second light received by an imaging surface;
a distribution measurer that measures a first optical electric-field distribution of an intensity and a phase of the first light at the imaging surface, based on the interference waveform signal;
a distribution simulator that simulates second optical electric-field distributions of the intensity and the phase of the first light at a plurality of planes having different distances from the imaging surface in a direction opposite to a propagation direction of the first light propagated from an end surface of an optical waveguide, based on the measured first optical electric-field distribution;
a selector that selects, from the plurality of planes, a plane at which an area of a region of the simulated second optical electric-field distributions is minimized; and
an outputter that outputs information of the simulated second optical electric-field distributions on the selected plane to a predetermined device.

2. The measurement apparatus according to claim 1, wherein the outputter outputs information on a propagation distance from the selected plane to the imaging surface to the predetermined device.

3. The measurement apparatus according to claim 1, wherein the distribution measurer measures the first optical electric-field distribution, based on the interference waveform signal of digital holography.

4. The measurement apparatus according to claim 1, wherein the imaging surface receives the first light propagated from the end surface of the optical waveguide without passing through an imaging optical system.

5. A measurement compensation device comprising:
a distribution measurer that measures a first optical electric-field distribution of an intensity and a phase of first light at an imaging surface, based on an interference waveform signal corresponding to interference light of the first light and second light received at the imaging surface;
a distribution simulator that simulates second optical electric-field distributions of the intensity and the phase of the first light at a plurality of planes having different distances from the imaging surface in a direction opposite to a propagation direction of the first light propagated from an end surface of an optical waveguide, based on the measured first optical electric-field distribution;
a selector that selects, from the plurality of planes, a plane at which an area of a region of the simulated second optical electric-field distributions is minimized; and
an outputter that outputs information of the simulated second optical electric-field distributions at the selected plane to a predetermined device.

6. A measurement method performed by a measurement apparatus, the measurement method comprising:
generating an interference waveform signal corresponding to interference light of first light with second light received by an imaging surface;
measuring a first optical electric-field distribution of an intensity and a phase of the first light at the imaging surface, based on the interference waveform signal;
simulating second optical electric-field distributions of the intensity and the phase of the first light at a plurality of planes having different distances from the imaging surface in a direction opposite to a propagation direction of the first light propagated from an end surface of an optical waveguide, based on the measured first optical electric-field distribution;
selecting, from the plurality of planes, a plane at which an area of a region of the simulated second optical electric-field distributions is minimized; and
outputting information of the simulated second optical electric-field distributions at the selected plane to a predetermined device.
